(19) United States
(12) Patent Application Publication
(10) Pub. No.: US 2018/0033940 A1
(43) Pub. Date: Feb. 1, 2018

(54) SPIN CURRENT-ELECTRIC CURRENT CONVERSION STRUCTURE, THERMOELECTRIC CONVERSION ELEMENT USING THE SAME, AND METHOD FOR MAKING THE SAME

(71) Applicant: NEC CORPORATION, Tokyo (JP)

(72) Inventors: Akihiro KIRIHARA, Tokyo (JP); Masahiko ISHIDA, Tokyo (JP); Kazuki IHARA, Tokyo (JP); Yuma IWASAKI, Tokyo (JP); Hiroko SOMEYA, Tokyo (JP)

(73) Assignee: NEC Corporation, Tokyo (JP)

(21) Appl. No.: 15/549,910

(22) PCT Filed: Feb. 17, 2016
(86) PCT No.: PCT/JP2016/000807

§ 371 Date: Aug. 9, 2017

(30) Foreign Application Priority Data
Feb. 26, 2015 (JP) 2015-036159

(51) Int. Cl. H01L 35/22; H01L 43/08; H01L 43/06; G11C 11/16; H01L 43/10; H01L 35/34; H01L 35/28; H01L 43/04

(52) U.S. Cl. CPC H01L 35/22; H01L 35/28; H01L 43/08; H01L 43/04; G11C 11/161; H01L 43/10; H01L 35/34; H01L 43/065

(57) ABSTRACT

A spin current-electric current conversion structure using a material containing 5d-transition metal has low efficiency of spin current-electric current conversion; therefore, a spin current-electric current conversion structure according to an exemplary aspect of the present invention includes a 4d-transition metal oxide structure consisting primarily of an oxide containing a 4d-transition-metal element; a spin current input-output structure configured to allow a spin current to flow into and out in a direction perpendicular to a plane of the 4d-transition metal oxide structure; and an electric current input-output structure configured to allow an electric current to flow into and out, the electric current conducting in an in-plane direction of the 4d-transition metal oxide structure.

### TECHNICAL FIELD

The present invention relates to spin current-electric current conversion structures, thermoelectric conversion elements using the structures, and methods for making the thermoelectric conversion elements and, in particular, to a spin current-electric current conversion structure using the spin Hall effect and the inverse spin Hall effect, a thermoelectric conversion element using the structure, and a method for making the thermoelectric conversion element.

### BACKGROUND ART

The expectations for thermoelectric conversion elements are rising as one of thermal management technologies for sustainable society. Heat is the most common energy source that can be recovered in various situations, such as body temperature, solar heat, waste heat produced from engines, and industrial waste heat. This makes it possible to predict that thermoelectric conversion technologies become increasingly important from now on in various uses such as promotion of energy use efficiency, power feeding to ubiquitous terminals and sensors, and thermal flow visualization by heat flow sensing.

In these circumstances, a thermoelectric conversion element based on the “spin Seebeck effect”, in which a current of spin angular momentum (spin current) is generated by applying a temperature gradient (temperature difference) to a magnetic material, has been developed in recent years. The thermoelectric conversion element based on the spin Seebeck effect is composed of a double-layered structure including a magnetic material layer having magnetization in a single direction and a conductive electromotive film. When a temperature gradient is applied to the element in a direction perpendicular to the plane of the element (normal direction), a current of spin angular momentum (spin current) is induced in the magnetic material due to the spin Seebeck effect. The spin current is injected into the electromotive film and converted into an electric current due to “the inverse spin Hall effect” in the electromotive film. This enables “the thermoelectric conversion” of generating electricity from a temperature gradient.

In order to obtain large electromotive force with such a thermoelectric conversion element, it is important to use a material in which the conversion between the spin current and the electric current is efficiently performed. As the material in which the spin current-electric current conversion is performed, platinum (Pt) with large spin Hall effect has been mainly used conventionally. Specifically, a thermoelectric conversion element can be formed by using single-crystal yttrium iron garnet (Y₃Fe₅O₁₂: YIG) that is a type of garnet ferrites as magnetic insulator and using platinum (Pt) wire as an electromotive film, for example. It is possible to use gold (Au), iridium (Ir), tantalum (Ta), tungsten (W), and the like for the electromotive film. These are transition metals belonging to the sixth period of the periodic table of the elements and materials falling into a category that is generally called 5d-transition metal. It is known that 5d-transition metal materials have large spin current-electric current conversion efficiency compared to other materials such as 4d-transition metals among metal element materials composed of a single element.

Patent Literature 1 discloses an example in which the spin current-electric current conversion is performed by using conductive oxide materials. An electric current-spin current conversion element described in Patent Literature 1 is configured to perform the conversion between electric current and spin current using the spin Hall effect or the inverse spin Hall effect of the 5d-transition metal oxide. It is also described that iridium oxide (IrO₂) is a material that exhibits a large spin Hall resistivity and spin Hall angle compared to platinum (Pt). This makes it possible, they say, to obtain the suggestion that iridium oxide (IrO₂) has promise as a material for electric current-spin current conversion elements.

In addition, Patent Literature 2 discloses related technologies.

### CITATION LIST

### Patent Literature

### [PTL 1] WO 2012/026168

### [PTL 2] Japanese Unexamined Patent Application Publication No. 2008-070336

### SUMMARY OF INVENTION

### Technical Problem

As mentioned above, 5d-transition metal materials and oxide materials containing 5d-transition-metal element have been mainly used for the spin current-electric current conversion structure. However, the spin current-electric current conversion structure containing 5d-transition metal element has the problem of low efficiency of the spin current-electric current conversion. Specifically, for example, if a thermoelectric conversion element using a 5d-transition metal material and the spin Seebeck effect is applied to a thermal flow sensor, the sensitivity of the thermal flow sensing is lower than that of an existing thermal flow sensor. Therefore, it is necessary to make the spin current-electric current conversion more efficient in order to achieve higher electromotive force of the thermoelectric conversion element.

As mentioned above, there is the problem that the spin current-electric current conversion structure using a material containing 5d-transition metal has low efficiency of spin current-electric current conversion.

An object of the present invention is to provide a spin current-electric current conversion structure that solves the above-mentioned problem that a spin current-electric current conversion structure using a material containing 5d-transition metal has low efficiency of spin current-electric current conversion, and provide a thermoelectric conversion element using the structure, and a method for making the thermoelectric conversion element.

### Solution to Problem

A spin current-electric current conversion structure according to an exemplary aspect of the present invention includes a 4d-transition metal oxide structure consisting primarily of an oxide containing a 4d-transition-metal element; a spin current input-output structure configured to allow a spin current to flow into and out in a direction perpendicular to a plane of the 4d-transition metal oxide structure; and an electric current input-output structure configured to allow an electric current to flow into and out, the electric current conducting in an in-plane direction of the 4d-transition metal oxide structure.

A thermoelectric conversion element according to an exemplary aspect of the present invention includes a magnetic material layer containing a magnetic material exhibiting spin Seebeck effect; and an electromotive material connected to the magnetic material layer so that a spin current can flow into and out, and configured to generate electromotive force due to inverse spin Hall effect, wherein the electromotive material includes a spin current-electric current conversion structure, which includes a 4d-transition metal oxide structure consisting primarily of an oxide containing a 4d-transition-metal element; a spin current input-output structure configured to allow a spin current to flow into and out in a direction perpendicular to a plane of the 4d-transition metal oxide structure; and an electric current input-output structure configured to allow an electric current to flow into and out, the electric current conducting in an in-plane direction of the 4d-transition metal oxide structure.

A memory element according to an exemplary aspect of the present invention includes a magnetic free layer; a barrier layer connected to the magnetic free layer; a magnetic fixed layer configured to form a tunnel junction with the magnetic free layer through the barrier layer; and a conductive layer disposed so that a spin current may arise due to spin Hall effect, and so that the spin current may flow into the magnetic free layer, wherein the conductive layer includes a spin current-electric current conversion structure, which includes a 4d-transition metal oxide structure consisting primarily of an oxide containing a 4d-transition-metal element; a spin current input-output structure configured to allow a spin current to flow into and out in a direction perpendicular to a plane of the 4d-transition metal oxide structure; and an electric current input-output structure configured to allow an electric current to flow into and out, the electric current conducting in an in-plane direction of the 4d-transition metal oxide structure.

A method for making a thermoelectric conversion element according to an exemplary aspect of the present invention includes stacking, on a substrate, a magnetic material layer containing a magnetic material exhibiting spin Seebeck effect; stacking, on the magnetic material layer, an electromotive material connected to the magnetic material layer so that a spin current can flow into and out, and configured to generate electromotive force due to inverse spin Hall effect; and forming two electrode sections apart from each other, each of which is electrically connected to the electromotive material, wherein the stacking of the electromotive material includes forming the electromotive material in such a way as to include a the spin current-electric current conversion structure, which includes a 4d-transition metal oxide structure consisting primarily of an oxide containing a 4d-transition-metal element; a spin current input-output structure configured to allow a spin current to flow into and out in a direction perpendicular to a plane of the 4d-transition metal oxide structure; and an electric current input-output structure configured to allow an electric current to flow into and out, the electric current conducting in an in-plane direction of the 4d-transition metal oxide structure.

### Advantageous Effects of Invention

According to the spin current-electric current conversion structure, the thermoelectric conversion element using the structure, and the method for making the thermoelectric conversion element of the present invention, it is possible to make the spin current-electric current conversion more efficient.

### BRIEF DESCRIPTION OF DRAWINGS

FIG. 1 is a perspective view illustrating the configuration of a spin current-electric current conversion structure according to a first example embodiment of the present invention.

FIG. 2 is a perspective view illustrating the configuration of a thermoelectric conversion element according to a second example embodiment of the present invention.

FIG. 3 is a perspective view illustrating the configuration of an evaluation thermoelectric conversion element according to the second example embodiment of the present invention.

FIG. 4 is a diagram illustrating the dependence on temperature difference of the thermoelectromotive force of the evaluation thermoelectric conversion element according to the second example embodiment of the present invention.

FIG. 5 is a diagram illustrating the dependence on anneal temperature of the thermoelectric coefficient of the evaluation thermoelectric conversion element according to the second example embodiment of the present invention.

FIG. 6 is a diagram illustrating the dependence on anneal temperature of the electric resistivity of a ruthenium oxide film included in the thermoelectric conversion element according to the second example embodiment of the present invention.

FIG. 7 is a perspective view illustrating the configuration of a memory element according to a third example embodiment of the present invention.

FIG. 8 is a diagram illustrating the dependence on temperature difference of the thermoelectromotive force of a thermoelectric conversion element according to example 1 of the present invention.

FIG. 9 is a perspective view illustrating the configuration of a thermoelectric conversion element according to example 2 of the present invention.

FIG. 10 is a diagram illustrating the dependence on temperature difference of the thermoelectromotive force of the thermoelectric conversion element according to example 2 of the present invention.

FIG. 11 is a perspective view illustrating the configuration of a memory element according to example 3 of the present invention.

### EXAMPLE EMBODIMENT

Example embodiments of the present invention will be described below with reference to the drawings.

### First Example Embodiment

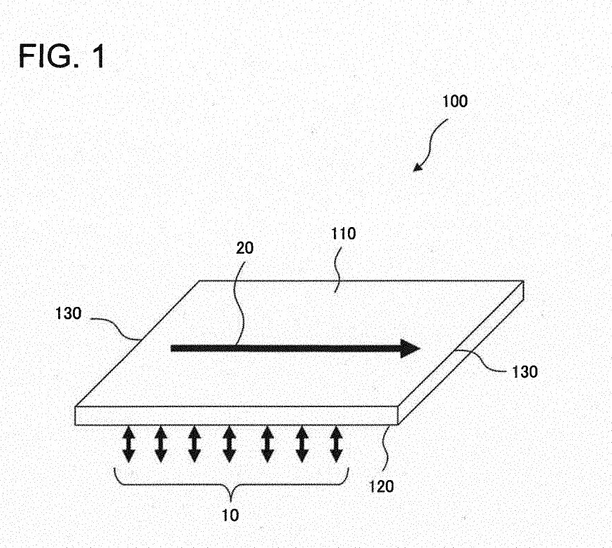

FIG. 1 is a perspective view illustrating the configuration of a spin current-electric current conversion structure 100 according to a first example embodiment of the present invention. The spin current-electric current conversion structure 100 includes a 4d-transition metal oxide structure 110, a spin current input-output structure 120, and an electric current input-output structure 130.

The 4d-transition metal oxide structure 110 consists primarily of an oxide containing a 4d-transition-metal element. The 4d-transition metal is one of transition metals belonging to the fifth period of the periodic table of the elements, and has the 4d-orbital occupied by electrons in the order of the atomic number from yttrium (Y) of atomic number 39 to silver (Ag) of atomic number 47.

The oxide containing a 4d-transition-metal element that constitutes the 4d-transition metal oxide structure 110 includes at least one of ruthenium oxide, rhodium oxide, and niobium oxide each of which has the rutile crystal structure.

The valence of the 4d-transition metal in the oxide containing the 4d-transition-metal element can be determined so that the spin Hall angle of the oxide containing the 4d-transition-metal element may be maximized. The spin Hall angle represents conversion efficiency between spin current and electric current, and is given by the ratio of the spin current to the electric current.

The spin current input-output structure 120 allows a spin current 10 to flow into and out in a direction perpendicular to the plane of the 4d-transition metal oxide structure 110. For example, the interface between the 4d-transition metal oxide structure 110 and a magnetic material can be used as the spin current input-output structure 120.

The electric current input-output structure 130 allows an electric current 20 to flow into and out, and the electric current 20 conducts in an in-plane direction of the 4d-transition metal oxide structure 110. For example, two terminals or electrode sections can be used as the electric current input-output structure 130, and the two terminals or electrode sections are electrically connected to the 4d-transition metal oxide structure 110 respectively and disposed apart from each other.

According to the spin current-electric current conversion structure 100 of the present example embodiment, the above-described configuration enables the spin current-electric current conversion to become more efficient.

The spin current-electric current conversion structure 100 of the present example embodiment is configured to include the 4d-transition metal oxide structure 110 that consists primarily of the oxide containing the 4d-transition-metal element. This makes it possible to achieve the effect of high stability and good corrosion-resistance of the material. As described above, the spin current-electric current conversion structure 100 of the present example embodiment enables spintronics devices such as thermoelectric conversion elements to improve in performance.

### Second Example Embodiment

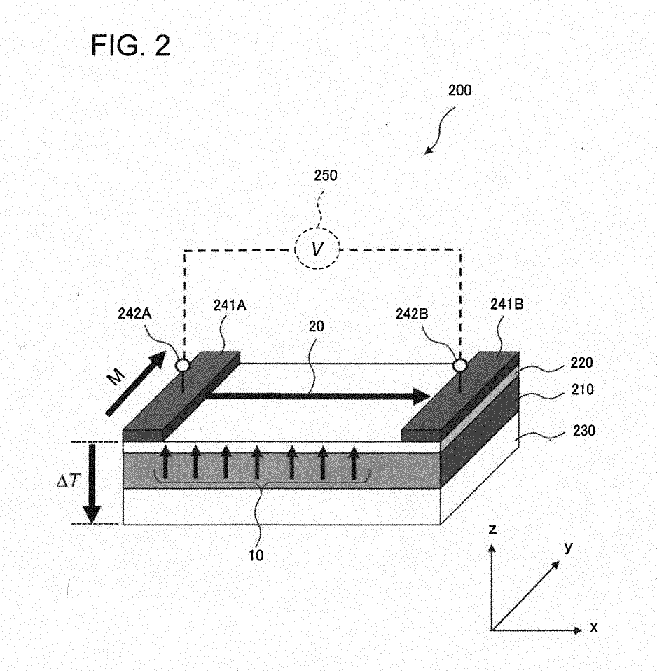

Next, a second example embodiment of the present invention will be described. FIG. 2 is a perspective view illustrating the configuration of a thermoelectric conversion element 200 according to the second example embodiment of the present invention. The thermoelectric conversion element 200 according to the present example embodiment is a thermoelectric conversion element using the spin current-electric current conversion structure according to the first example embodiment as an electromotive material.

The thermoelectric conversion element 200 includes a magnetic material layer 210 and a conductive 4d-transition metal oxide layer 220 that serves as the electromotive material. The magnetic material layer 210 contains a magnetic material exhibiting the spin Seebeck effect. The conductive 4d-transition metal oxide layer 220 is connected to the magnetic material layer 210 so that a spin current can flow into and out, and generates electromotive force (electric current 20) due to the inverse spin Hall effect. The conductive 4d-transition metal oxide layer 220 is configured to include the spin current-electric current conversion structure according to the first example embodiment.

The thermoelectric conversion element 200 can be configured to further include a substrate 230 on which the magnetic material layer 210 is mounted, and two electrode sections that are electrically connected to the conductive 4d-transition metal oxide layer 220 and disposed apart from each other. The interface between the conductive 4d-transition metal oxide layer 220 and the magnetic material layer 210 configures the spin current input-output structure 120, and the electrode sections configure the electric current input-output structure 130. As illustrated in FIG. 2, the electrode sections may be composed of pad sections 241A and 241B and terminal sections 242A and 242B.

The magnetic material layer 210 is made of a magnetic material that exhibits the spin Seebeck effect, and generates a spin current 10 (Js) from a temperature gradient, nabla T (temperature difference ΔT), in a direction perpendicular to the plane of the layer (normal direction) due to the spin Seebeck effect. The direction of the spin current Js is parallel or antiparallel to that of the temperature gradient, nabla T. In the example illustrated in FIG. 2, the temperature gradient, nabla T, is applied in the minus z direction, and the spin current Js along the plus z or minus z direction is generated.

Materials such as yttrium iron garnet (Y₃Fe₅O₁₂: YIG), YIG doped with bismuth (Bi) (Bi: YIG, BiY₂Fe₅O₁₂), or Ni—Zn ferrite ((Ni, Zn)ₓFe₃₋ₓO₄) can be used for the magnetic material layer 210. The smaller the thermal conductivity of the magnetic material layer 210 is, the larger the thermoelectric conversion efficiency becomes. Consequently, it is preferable to use, as the magnetic material layer 210, a magnetic insulator through which the electric current does not flow, that is, electrons do not transport heat.

The conductive 4d-transition metal oxide layer 220 converts the spin current 10 arising and inflowing due to the spin Seebeck effect in the magnetic material layer 210 into the electromotive force (electric current 20) due to the inverse spin Hall effect. In other words, the conductive 4d-transition metal oxide layer 220 generates the electromotive force from the spin current Js due to the inverse spin Hall effect, which causes the electric current 20 to flow. Thus the conductive 4d-transition metal oxide layer 220 functions as the spin current-electric current conversion structure.

The direction of the electromotive force (electric field E) generated above is given by the cross product of the direction of the magnetization M in the magnetic material layer 210 and the direction of the temperature gradient, nabla T. That is to say, there is a relation of E˜M×nabla T. The thermoelectric conversion element 200 of the present example embodiment is configured so that the direction of the electromotive force may be an in-plane direction of the conductive 4d-transition metal oxide layer 220 that serves as the electromotive material. In the example illustrated in FIG. 2, the direction of the magnetization M of the magnetic material layer 210 is the plus y direction, the direction of the temperature gradient, nabla T, is the minus z direction, and the direction of the electromotive force is the minus x direction.

The oxide materials containing the 4d-transition-metal element such as a ruthenium oxide (RuOₓ) conductive film, rhodium oxide (RhOₓ), and niobium oxide (NbOₓ) can be used as the conductive 4d-transition metal oxide layer 220. It is preferable for the thickness of the conductive 4d-transition metal oxide layer 220 in the direction perpendicular to the plane to be nearly equal to the spin diffusion length of the 4d-transition metal oxide contained in the layer, and the thickness is preferably not less than 2 nanometers (nm) and not more than 30 nanometers (nm).

The pad sections 241A and 241B are disposed at both ends of, electrically connected to, the conductive 4d-transition metal oxide layer 220. This makes it possible to extract the electromotive force efficiently from the thin-film conductive 4d-transition metal oxide layer 220 to the outside. It is preferable to use metal materials having small resistivity as the pad sections 241A and 241B, and materials such as gold (Au), platinum (Pt), tantalum (Ta), and copper (Cu) can be used, for example. It is preferable for the film thickness of the pad sections 241A and 241B to be thicker than that of the conductive 4d-transition metal oxide layer 220, and to be not less than 30 nanometers (nm).

The electromotive force is extracted to the outside through the terminal sections 242A and 242B that are connected to the pad sections 241A and 241B, respectively. If the thermoelectric conversion element 200 is used as a thermal flow sensor, for example, the amount of heat flowing through the thermoelectric conversion element 200 can be evaluated by measuring the open voltage between the two terminal sections 242A and 242B by a voltmeter 250.

The electrode section may have a configuration in which the terminal sections 242A and 242B are formed directly on the conductive 4d-transition metal oxide layer 220 without the pad sections 241A and 241B.

Next, a method for making the thermoelectric conversion element 200 according to the present example embodiment will be described.

In the method for making the thermoelectric conversion element 200 of the present example embodiment, first, the magnetic material layer 210 containing a magnetic material exhibiting the spin Seebeck effect is stacked on the substrate 230. On the magnetic material layer 210, the conductive 4d-transition metal oxide layer 220 is stacked that serves as an electromotive material that is connected to the magnetic material layer 210 so that a spin current can flow into and out, and generates electromotive force due to the inverse spin Hall effect. Finally, two electrode sections each of which is electrically connected to the conductive 4d-transition metal oxide layer 220 are formed apart from each other, which completes the thermoelectric conversion element 200. In stacking the conductive 4d-transition metal oxide layer 220, the conductive 4d-transition metal oxide layer 220 is formed in such a way as to include the spin current-electric current conversion structure according to the first example embodiment.

In order to form the magnetic material layer 210, any one of the methods can be used that include a sputtering method, a metal organic decomposition (MOD) method, a pulsed laser deposition (PLD) method, a sol-gel method, an aerosol deposition (AD) method, a ferrite plating method, and a liquid phase epitaxy (LPE) method.

In order to form the conductive 4d-transition metal oxide layer 220, methods can be used that include a reactive sputtering method in the presence of oxygen and the metal organic decomposition (MOD) method. In order to form the pad sections 241A and 241B, methods can be used that include the sputtering method, a vacuum deposition method, an electron beam deposition method, and a plating method.

According to the above-mentioned thermoelectric conversion element 200 and the method for making the thermoelectric conversion element, it is possible to make the spin current-electric current conversion more efficient. The effect of the thermoelectric conversion element 200 according to the present example embodiment will be described in more detail below.

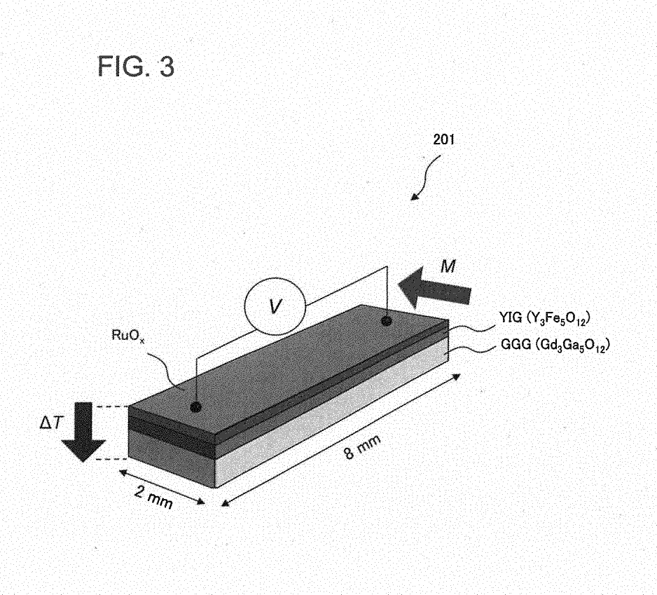

In order to verify the above-mentioned effect, an evaluation thermoelectric conversion element 201 illustrated in FIG. 3 was prepared and evaluated. As illustrated in the figure, a ruthenium oxide (RuOₓ) conductive film was used as the conductive 4d-transition metal oxide layer 220.

The evaluation thermoelectric conversion element 201 was made as follows. First, an yttrium iron garnet (Y₃Fe₅O₁₂: YIG) magnetic film 120 nanometers (nm) thick was formed on a gadolinium gallium garnet (Gd₃Ga₅O₁₂: GGG) substrate approximately 0.5 millimeters (mm) thick. A ruthenium oxide (RuOₓ) conductive film 10 nanometers (nm) thick was formed on the above-described magnetic film. The metal organic decomposition (MOD) method included in coating-based deposition methods was used in order to form the YIG magnetic film. Specifically, the YIG magnetic film was formed by applying a solution of an organic metal (MOD solution) containing yttrium (Y) and iron (Fe) by spin coat technology at a rotational speed of approximately 1,000 rpm (revolution per minute), and then annealing it at approximately 700° C.

The ruthenium oxide (RuOₓ) conductive film was formed by using the reactive sputtering method. The reactive sputtering was performed under conditions that a ruthenium (Ru) target was used at room temperature at approximately 0.5 Pa pressure (argon Ar flow rate of 2.9 sccm, and oxygen O₂ flow rate of 7.5 sccm). Although the stoichiometric stable composition of the ruthenium oxide is expressed in RuO₂, an oxygen defect or an excess of oxygen arises depending on fabrication conditions such as heat treatment. Accordingly, post-annealing for approximately one hour was performed under atmospheric conditions or nitrogen (N₂) flow conditions in different temperature conditions (anneal temperature Tₐₙ) after the sputtering. Then the evaluation was performed on a plurality of evaluation thermoelectric conversion elements 201 that differ in oxidation state.

For comparison of the performance of the evaluation thermoelectric conversion element 201, a comparative thermoelectric conversion element was also made that used, as a conductive film, platinum (Pt) generally used as a conductive film for spin Seebeck elements or iridium oxide (IrOₓ) included in the 5d-transition metal oxide. The comparative thermoelectric conversion element using platinum (Pt) was made by the same production method as the above-described production method. In other word, on a GGG (Gd₃Ga₅O₁₂) substrate was formed a YIG (Y₃Fe₅O₁₂) magnetic film 120 nanometers (nm) thick, on which a platinum (Pt) film 10 nanometers (nm) thick was formed by using the sputtering method, by which the comparative thermoelectric conversion element was made. Regarding the comparative thermoelectric conversion element using iridium oxide (IrOₓ), the YIG (Y₃Fe₅O₁₂) magnetic film was formed in a similar way, and then an iridium oxide (IrOₓ) film 10 nanometers (nm) thick was formed by using the reactive sputtering using an iridium (Ir) target. The condition of the reactive sputtering was the same as that for forming the above-mentioned ruthenium oxide (RuOₓ) conductive film. Then post-annealing was performed at approximately 400° C. in the atmosphere.

The wafer produced in the above-mentioned processes was cut in the shape of a sample approximately two-by-eight millimeters (mm), and its thermoelectric properties were evaluated with the temperature gradient (temperature difference ΔT) illustrated in FIG. 3 applied. If the temperature difference ΔT is applied in the thickness direction (perpendicular to the plane) of the element including the substrate as seen above, the electromotive force V is generated in an in-plane direction perpendicular to both the direction of the magnetization M of the magnetic film and that of the temperature gradient. In this instance, the direction (sign) and magnitude of the electromotive force are determined by the spin Hall angle that is a parameter inherent in the conductive material.

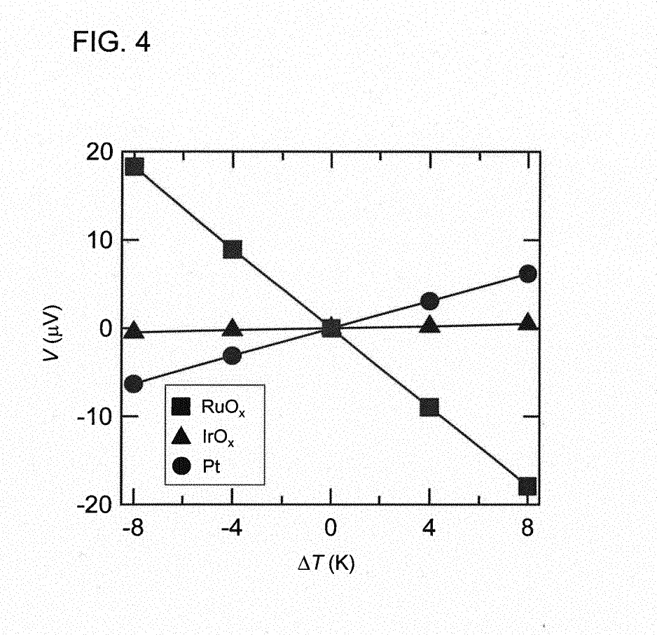

FIG. 4 illustrates the dependence of the thermoelectromotive force V of the evaluation thermoelectric conversion element 201 on the temperature difference ΔT. The evaluation thermoelectric conversion element 201 had the above-mentioned RuOₓ/YIG/GGG structure, on which the annealing treatment was performed under the conditions of the temperature Tₐₙ=600° C. and nitrogen (N₂) flow. The diagram also illustrates the evaluation results of the comparative thermoelectric conversion element having the IrOₓ/YIG/GGG structure and annealed in the atmosphere at the temperature Tₐₙ=400° C. and the comparative thermoelectric conversion element having the Pt/YIG/GGG structure.

As can be seen from FIG. 4, the dependence on temperature difference of the thermoelectromotive force of the evaluation thermoelectric conversion element 201 having the ruthenium oxide (RuOₓ) conductive film is opposite in sign to that of the comparative thermoelectric conversion element using platinum (Pt) or iridium oxide (IrOₓ). The absolute value of the thermoelectric coefficient of the evaluation thermoelectric conversion element 201 was 2.2μ, V/K, which was approximately three times as large as that of the comparative thermoelectric conversion element using platinum (Pt) and approximately 40 times as large as that of the comparative thermoelectric conversion element using iridium oxide (IrOₓ).

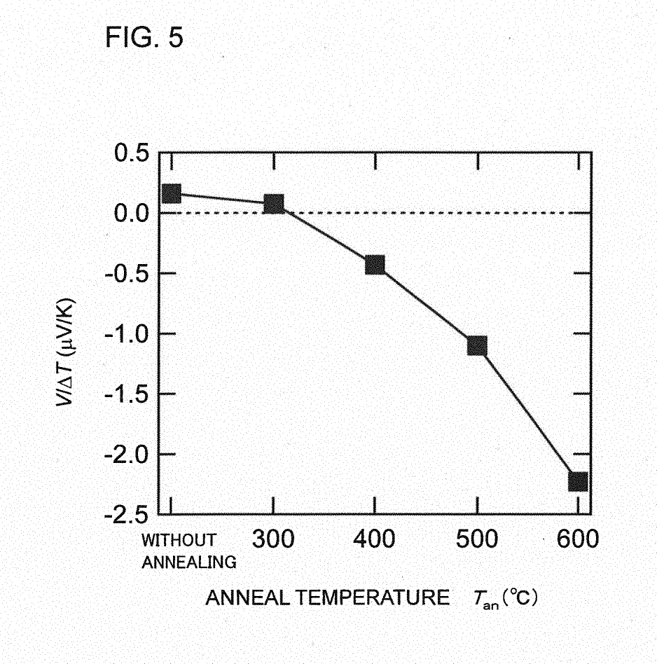

FIG. 5 illustrates the dependence on post-anneal temperature Tₐₙ of the thermoelectric coefficient V/ΔT of the evaluation thermoelectric conversion element 201 having the RuOₓ/YIG/GGG structure. As can be seen from the diagram, the thermoelectric performance significantly depends on the anneal temperature Tₐₙ. That is to say, the evaluation thermoelectric conversion element treated at the anneal temperature Tₐₙ of 300° C. has thermoelectromotive force smaller than that of the element without annealing treatment. However, it can be seen that the thermoelectromotive force is reversed in sign in the evaluation thermoelectric conversion element with the annealing treatment at 400° C., and the thermoelectromotive force increases raising the anneal temperature further.

It can be obtained as new insight from the result that the efficiency in spin current-electric current conversion also varies depending on the oxidation state of the 4d-transition metal oxide, that is, the valence of the 4d-transition metal ion. This enables the spin current-electric current property to be optimized by controlling the valence of the metal ion by a process such as annealing treatment. In other words, the method for making the thermoelectric conversion element can be configured to include a process for performing thermal treatment so that a valence of the 4d-transition metal in the 4d-transition metal oxide containing a 4d-transition-metal element may have a value by which to maximize the spin current-electric current conversion efficiency, that is, the spin Hall angle of the oxide containing a 4d-transition-metal element. It is preferable to perform the annealing treatment in the approximately 500° C. to 650° C. range for the above-mentioned evaluation thermoelectric conversion element 201 including the ruthenium oxide (RuOₓ) conductive film.

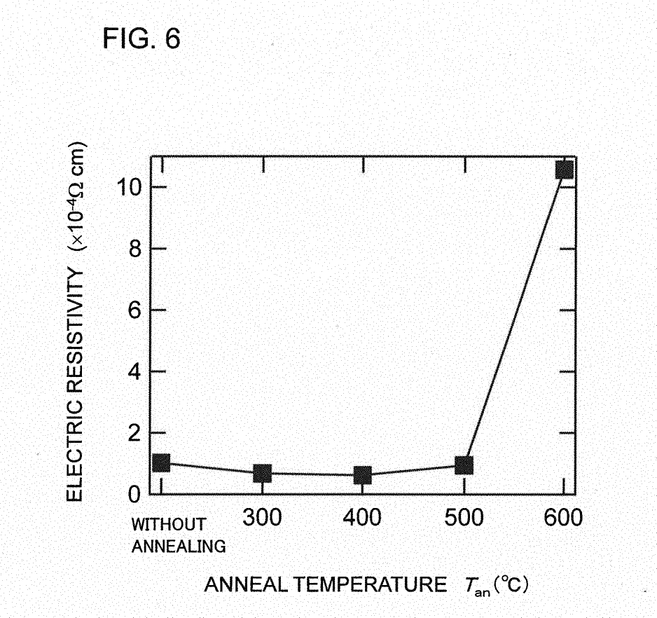

FIG. 6 illustrates the dependence of the electric resistivity of ruthenium oxide (RuOₓ) on the anneal temperature Tₐₙ. The four-terminal measurement method was used for the measurement of the electric resistivity. It can be seen from the diagram that the electric conduction property of ruthenium oxide (RuOₓ) also varies depending on the anneal temperature. The electric resistivity reaches, at the anneal temperature Tₐₙ of 400° C., a minimum of 6.2×10⁻⁵ Ωcm, which is close to the values that has been reported in the literature. On the other hand, the electric resistivity increases when the anneal temperature is further raised; consequently, when the annealing treatment is performed at 600° C., the electric resistivity is equal to 1.06×10⁻³ Ωcm, which is an order of magnitude or more greater than that with annealing at 400° C. It was found that the conductivity disappeared when the annealing was performed at 700° C. or higher.

It is clear from the above-described results that a great spin current-electric current conversion effect can be obtained according to the thermoelectric conversion element 200 of the present example embodiment using ruthenium oxide (RuOₓ), a conductive 4d-transition metal oxide, as an electromotive film. As a result, a thermoelectric conversion output voltage can be obtained that is larger than that of the thermoelectric conversion element using a conductive 5d-transition metal oxide or platinum (Pt) of noble metal as the electromotive film.

For single metal element, more efficient spin current-electric current conversion can be achieved as the element gets heavy with atomic weight larger because the spin orbit interaction is enhanced. In other words, 5d-transition metal generally has greater spin current-electric current conversion effect than 4d-transition metal has. In contrast, if transition metal oxides are used, the thermoelectric conversion element 200 according to the present example embodiment using 4d-transition metal oxide has greater spin current-electric current conversion effect than the comparative thermoelectric conversion element using 5d-transition metal has. This result is contrary to the above-mentioned empirical rule for single metal element that has previously been known. Therefore, it is clear that the configuration of the thermoelectric conversion element 200 according to the present example embodiment cannot be easily conceived from the configurations of these publicly known thermoelectric conversion elements.

As mentioned above, according to the thermoelectric conversion element 200 and the method for making the element of the present example embodiment, it is possible to make the spin current-electric current conversion more efficient. This makes it possible to obtain a large output voltage (electromotive force); therefore, it becomes possible to achieve high sensitivity for thermal flow sensing and the like.

In addition, according to the thermoelectric conversion element 200 and the method for making the element of the present example embodiment, it is possible to configure a thermoelectric conversion element relatively inexpensively. In contrast, conventional thermoelectric conversion elements using 5d-transition metal have the problem that material costs are high. That is to say, the 5d-transition metal such as platinum (Pt), gold (Au), and iridium (Ir) is noble metal; consequently, the material cost is high. As a result, there has been the problem that it is difficult to apply materials for spin current-electric current conversion containing 5d-transition metal to large area elements.

In addition, the thermoelectric conversion element 200 and the method for making the element of the present example embodiment produce the effect of high stability and high corrosion resistance of the material because the oxide is used as the conductive film (electromotive material). That is to say, the stability of the material is extremely important because thermoelectric conversion element is often used under harsh circumstances such as high-temperature and humidity. Metal materials generally have challenges such as easily-oxidizable and corrosion-prone properties at high temperature. In particular, 5d-transition metal materials such as tantalum (Ta) and tungsten (W) are easily oxidized at high temperature, and are problematic in terms of reliability depending on its application. In contrast, it is possible to avoid the above-described problems because the oxide materials are less likely to corrode and highly stable.

### Third Example Embodiment

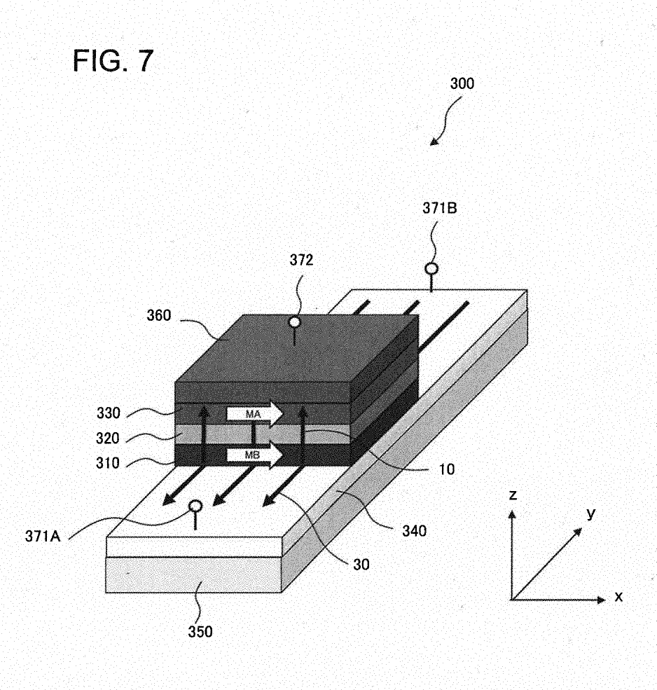

Next, a third example embodiment of the present invention will be described. FIG. 7 is a perspective view illustrating the configuration of a memory element 300 according to the third example embodiment of the present invention. The memory element 300 of the present example embodiment is a memory element using the spin current-electric current conversion structure according to the first example embodiment as a conductive layer.

The memory element 300 includes a magnetic free layer 310, a barrier layer 320 connected to the magnetic free layer 310, a magnetic fixed layer 330 to form a tunnel junction with the magnetic free layer 310 through the barrier layer 320, and a conductive 4d-transition metal oxide film 340 as a conductive layer. The conductive 4d-transition metal oxide film 340 is disposed so that a spin current may arise due to the spin Hall effect, and the spin current 10 may flow into the magnetic free layer 310. The conductive 4d-transition metal oxide film 340 is configured to include the spin current-electric current conversion structure according to the first example embodiment. These configurations can be disposed on a substrate 350.

The memory element 300 is capable of performing the operation of writing information by an electric current and the operation of reading out information by resistance detection. The writing operation is performed by passing a writing electric current 30 between both terminals of writing electrode terminals 371A and 371B that are electrically connected to both ends of the conductive 4d-transition metal oxide film 340. In the reading-out operation, the stored information can be detected by measuring a resistance in the stacked direction of the magnetic free layer 310, the barrier layer 320, and the magnetic fixed layer 330. In order to detect the resistance, the memory element can be configured to include a reading-out electrode 360 electrically connected to the magnetic fixed layer 330 and a reading-out electrode terminal 372 electrically connected to the reading-out electrode 360.

The magnetic free layer 310 and the magnetic fixed layer 330 have in-plane magnetization in the x direction of each layer, and form a tunnel junction through the barrier layer 320. The magnetic fixed layer 330 has sufficiently large coercivity, and has a fixed magnetization MA with the magnetization always fixed in the plus x direction. In contrast, the magnetization direction of the magnetic free layer 310 is defined as any one of plus x and minus x direction and is inverted by external drive that is called spin torque. In other words, the magnetic free layer 310 has a variable magnetization MB. The magnetization direction of the magnetic free layer 310 becomes parallel or antiparallel to that of the magnetic fixed layer 330 depending on the magnetization direction of the magnetic free layer 310; consequently, the resistance of the tunnel junction changes. The resistance change corresponds to the information ‘0’ or ‘1’ for the memory element 300.

The conductive 4d-transition metal oxide film 340 is disposed below the magnetic free layer 310 in order to write and rewrite the information into the memory element 300. The operation of writing and rewriting the information can be performed by passing a writing electric current between the writing electrode terminal 371A and the writing electrode terminal 371B that are electrically connected to both ends of the conductive 4d-transition metal oxide film 340.

Specifically, when the writing electric current 30 is passed in the minus y direction in FIG. 7 through the conductive 4d-transition metal oxide film 340, a part of the writing electric current 30 is converted, due to the spin Hall effect, into a spin current in the z direction, that is, a flow in the z direction of the spin angular momentum in the x direction. The conductive 4d-transition metal oxide film 340, therefore, functions as the spin current-electric current conversion structure. This spin current 10 is injected into the magnetic free layer 310 and inverts the magnetization of the magnetic free layer 310 by applying the spin torque to the magnetic free layer 310. This makes it possible to rewrite the information.

Oxide materials containing 4d-transition-metal element such as ruthenium oxide (RuOₓ) conductive film, rhodium oxide (RhOₓ), and niobium oxide (NbOₓ) are used as the conductive 4d-transition metal oxide film 340. It is preferable for the film thickness to be nearly equal to the spin diffusion length of the 4d-transition metal oxide material to be used, and the thickness is preferably not less than 3 nanometers (nm) and not more than 30 nanometers (nm).

Ferromagnetic materials such as CoFeB, cobalt (Co), and iron (Fe) can be used as the magnetic free layer 310 and the magnetic fixed layer 330. Insulating materials such as magnesium oxide (MgO) and aluminum oxide (Al₂O₃) can be used as the barrier layer 320. Each film thickness of the magnetic free layer 310 and the magnetic fixed layer 330 preferably ranges from approximately 1 nanometer (nm) to approximately 20 nanometers (nm), and the film thickness of the barrier layer 320 preferably ranges from approximately 0.3 nanometers (nm) to approximately 3 nanometers (nm). Materials such as tantalum (Ta) and gold (Au) can be used as the reading-out electrode 360.

Next, a method for making the memory element 300 according to the present example embodiment will be described.

In the method for making the memory element 300 according to the present example embodiment, first, the conductive 4d-transition metal oxide film 340 is formed by using a reactive sputtering method in the presence of oxygen or a metal organic decomposition (MOD) method. The region on the conductive 4d-transition metal oxide film 340 where to form a magnetic tunnel junction is patterned with resist by using a method such as a photolithography method and an electron beam lithography method. Then the magnetic free layer 310, the barrier layer 320, the magnetic fixed layer 330, and the reading-out electrode 360 are formed, respectively. A method such as a sputtering method can be used for the formation of these films. Finally, the resist is removed by using a lift-off process; consequently, a pillar-like magnetic tunnel junction is formed. This completes the memory element 300.

### Example 1

An example of the method for making the thermoelectric conversion element according to the second example embodiment of the present invention will be described below.

The thermoelectric conversion element 200 according to the second example embodiment is configured to include the conductive 4d-transition metal oxide layer 220 of a conductive oxide film that serves as an electromotive material. For the formation of the conductive oxide film, a non-vacuum process by a coating method can be used. This makes it possible to perform all steps in the process for making the thermoelectric conversion element together with the formation of a magnetic insulator film such as YIG by using a coating-based formation method. In the present example, the description will be made for a method for making the thermoelectric conversion element by such an all-coating-based process and for the characteristics of the thermoelectric conversion element obtained by the method.

Both the magnetic insulator film (YIG) and the conductive film (RuOₓ) were formed using a metal organic decomposition (MOD) method that is a coating-based film-formation method. In accordance with the MOD method, an oxide film can be formed by applying an organometallic solution containing a metal ion such as yttrium (Y), iron (Fe), and ruthenium (Ru) using a spin-coat method and by annealing the applied solution.

In the present example, a YIG film 120 nanometers (nm) thick was formed under the condition that a rotational speed of spin-coating was 1,000 rpm, and an anneal temperature was 700° C. Then a RuOₓ film approximately 40 nanometers (nm) thick was formed on the YIG film by using a coating method under the condition that a rotational speed of spin-coating was 4,000 rpm, and an anneal temperature in nitrogen (N₂) atmosphere was 600° C. The thermoelectric conversion element made by the above-described processes was cut into a specimen with an area of approximately 8×2 mm². The resistance of the RuOₓ film in this specimen was 6.7 kΩ.

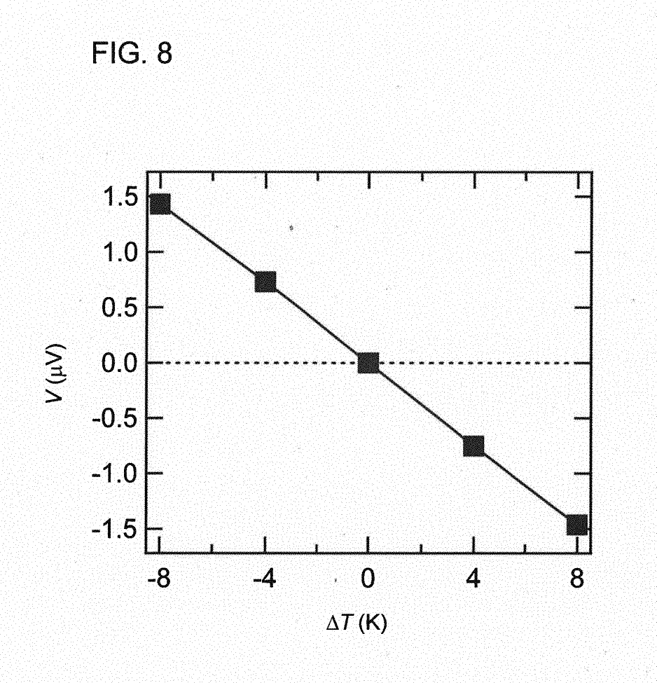

FIG. 8 illustrates the dependence on the temperature difference ΔT of the electromotive force V of the thermoelectric conversion element according to the present example. The evaluation was performed by a method similar to that in the second example embodiment. As illustrated in the diagram, clear signals of thermoelectromotive force proportional to the temperature difference ΔT were observed. This validates for the first time the fact that a thermoelectric conversion element (spin thermoelectric element) was able to be fabricated by the all-coating-based process. The sign of the electromotive force is the same as that of the thermoelectric conversion element 200 including the RuOₓ film formed by the sputtering method and post-annealing described in the second example embodiment (see FIG. 4), but it is opposite to that of the element using platinum (Pt).

The magnitude of the output voltage is smaller than that of the thermoelectric conversion element 200 including the RuOₓ film formed by the sputtering method according to the second example embodiment (see FIG. 4). This is because the RuOₓ film used in the present example is thick, approximately 40 nanometers (nm) thick. As a result, it is preferable for the film thickness of the RuOₓ film to be equal to or less than 30 nanometers (nm).

### Example 2

Another example of the thermoelectric conversion element and the method for making the element according to the second example embodiment of the present invention will be described below.

In the present example, a thermoelectric conversion element is described that uses rhodium oxide (RhOₓ) instead of ruthenium oxide (RuOₓ) as the 4d-transition metal oxide material.

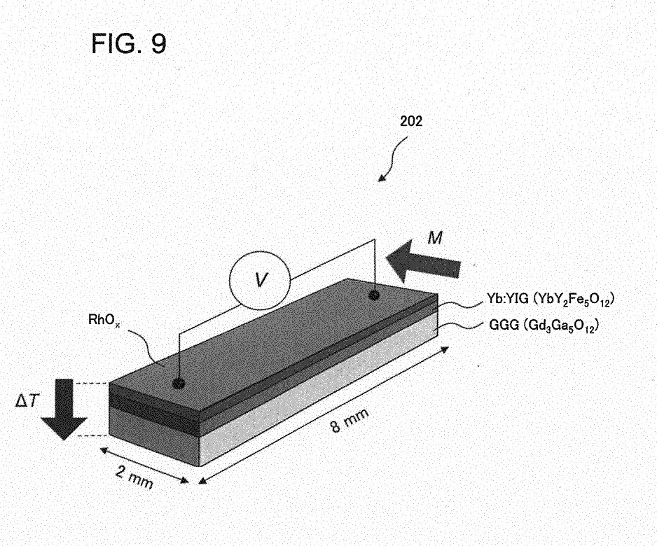

FIG. 9 is a perspective view of a thermoelectric conversion element 202 according to the present example. A GGG substrate that is made of the same material as that of the substrate used for the evaluation thermoelectric conversion element 201 according to the second example embodiment was used for a substrate, and ytterbium (Yb)-doped YIG (YbY₂Fe₅O₁₂) 60 nanometers (nm) thick was used as a magnetic material layer. The Yb-doped YIG film was formed by a process similar to the process using the metal organic decomposition method (MOD method) in the second example embodiment.

The rhodium oxide (RhOₓ) film was formed using the reactive sputtering method as is the case with the second example embodiment. The reactive sputtering was performed under conditions that a rhodium (Rh) target was used at room temperature at 0.5 Pa pressure (Ar flow rate of 2.9 sccm, and O₂ flow rate of 7.5 sccm).

Although the stoichiometric stable composition of rhodium oxide (RhOₓ) is expressed in RhO₂, an oxygen defect or an excess of oxygen arises depending on fabrication conditions such as heat treatment. Accordingly, post-annealing for one hour was performed under atmospheric conditions or nitrogen (N₂) flow conditions in different temperature conditions (anneal temperature Tₐₙ) after the sputtering, as is the case in RuOₓ according to the second example embodiment. Thus a plurality of samples were prepared that differed in oxidation state of a RhOₓ film.

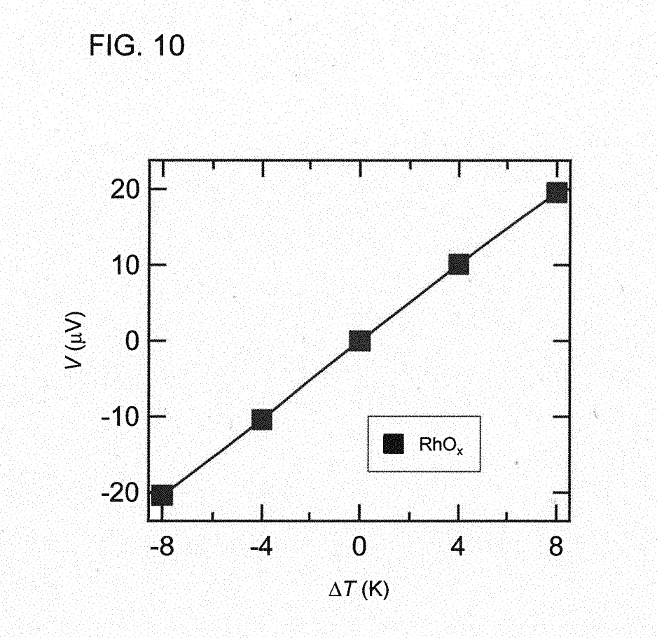

FIG. 10 illustrates the dependence on the temperature difference ΔT of the thermoelectromotive force V of the thermoelectric conversion element having a RhOₓ/Yb:YIG/GGG structure. This element is subjected to anneal treatment under the conditions of the temperature Tₐₙ equal to 600° C. and nitrogen (N₂) flow.

The thermoelectromotive force larger than that of the element using platinum (Pt) was achieved, as is the case with the evaluation thermoelectric conversion element 201 having the RuOₓ/YIG/GGG structure according to the second example embodiment. The sign of the electromotive force is opposite to that of the RuOₓ film after annealing used in the second example embodiment and Example 1, and it is the same as that of the element using platinum (Pt).

As described in the above-mentioned second example embodiment and example, a high-performance spin current-electric current conversion structure can be achieved by using the conductive 4d-transition metal oxide having the rutile crystal structure such as ruthenium oxide (RuOₓ) and rhodium oxide (RhOₓ).

### Example 3

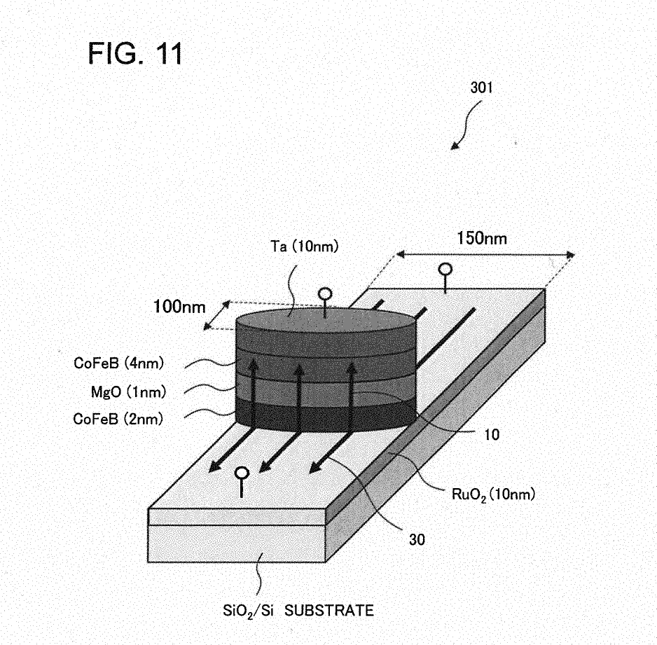

An example of the memory element and the method for making the memory element according to the third example embodiment of the present invention will be described below. FIG. 11 illustrates the configuration of a memory element 301 according to the present example.

A thermal silicon oxide (SiO₂/Si) substrate that was oxidized to a depth of 100 nanometers (nm) from the surface was used as a substrate. A conductive 4d-transition metal oxide film composed of RuOₓ 10 nanometers (nm) thick was formed on the substrate by using the reactive sputtering and post-annealing.

Then the region where to form the magnetic tunnel junction was patterned with resist by using an electron beam lithography method. Subsequently, Co₂₀Fe₆₀B₂₀ 2 nanometers (nm) thick serving as a magnetic free layer, MgO 1 nanometer (nm) thick serving as a barrier layer, and Co₂₀Fe₆₀B₂₀ 4 nanometers (nm) thick serving as a magnetic fixed layer were formed. In addition, tantalum (Ta) 10 nanometers (nm) thick serving as a reading-out electrode was formed sequentially by using the sputtering method. Finally, the resist was removed by lift-off process; consequently, a pillar-like magnetic tunnel junction was formed. The pillar had an elliptical shape, and was formed so that the major axis may become equal to 150 nanometers (nm) and minor axis may become equal to 100 nanometers (nm).

The memory element using a conductive 4d-transition metal oxide as a spin current-electric current conversion structure was fabricated by the above-described steps.

As described above, the present invention has been described by using the above example embodiments as typical examples. However, the present invention is not limited to the above example embodiments. In other words, various aspects of the present invention that are conceivable to those skilled in the art can be applied within the scope of the present invention.

This application is based upon and claims the benefit of priority from Japanese patent application No. 2015-036159, filed on Feb. 26, 2015, the disclosure of which is incorporated herein in its entirety by reference.

### REFERENCE SIGNS LIST

100 spin current-electric current conversion structure
110 4d-transition metal oxide structure
120 spin current input-output structure
130 electric current input-output structure
200, 202 thermoelectric conversion element
201 evaluation thermoelectric conversion element
210 magnetic material layer
220 conductive 4d-transition metal oxide layer
230 substrate
241A, 241B pad section
242A, 242B terminal
250 voltmeter
300, 301 memory element
310 magnetic free layer
320 barrier layer
330 magnetic fixed layer
340 conductive 4d-transition metal oxide film
350 substrate
360 reading-out electrode
371A, 371B electrode terminal
372 reading-out electrode terminal
10 spin current
20 electric current
30 writing current

1. A spin current-electric current conversion structure, comprising:
a 4d-transition metal oxide structure consisting primarily of an oxide containing a 4d-transition-metal element;
a spin current input-output structure configured to allow a spin current to flow into and out in a direction perpendicular to a plane of the 4d-transition metal oxide structure; and
an electric current input-output structure configured to allow an electric current to flow into and out, the electric current conducting in an in-plane direction of the 4d-transition metal oxide structure.

2. The spin current-electric current conversion structure according to claim 1,
wherein a valence of the 4d-transition metal in the oxide containing the 4d-transition-metal element is determined so that a spin Hall angle of the oxide containing the 4d-transition-metal element may be maximized.

3. The spin current-electric current conversion structure according to claim 1,
wherein the oxide containing the 4d-transition-metal element includes at least one of ruthenium oxide, rhodium oxide, and niobium oxide.

4. The spin current-electric current conversion structure according to claim 1,
wherein a thickness of the oxide containing the 4d-transition-metal element in a direction perpendicular to a plane of the oxide is not less than two nanometers and not more than thirty nanometers.

5. A thermoelectric conversion element, comprising:
a magnetic material layer containing a magnetic material exhibiting spin Seebeck effect; and
an electromotive material connected to the magnetic material layer so that a spin current can flow into and out, and configured to generate electromotive force due to inverse spin Hall effect,
wherein the electromotive material includes a spin current-electric current conversion structure, and
the spin current-electric current conversion structure includes
a 4d-transition metal oxide structure consisting primarily of an oxide containing a 4d-transition-metal element,
a spin current input-output structure configured to allow a spin current to flow into and out in a direction perpendicular to a plane of the 4d-transition metal oxide structure, and
an electric current input-output structure configured to allow an electric current to flow into and out, the electric current conducting in an in-plane direction of the 4d-transition metal oxide structure.

6. The thermoelectric conversion element according to claim 5, further comprising
a substrate on which the magnetic material layer is mounted, and
two electrode sections electrically connected to the electromotive material and disposed apart from each other.

7. A memory element, comprising:
a magnetic free layer;
a barrier layer connected to the magnetic free layer;
a magnetic fixed layer configured to form a tunnel junction with the magnetic free layer through the barrier layer; and
a conductive layer disposed so that a spin current may arise due to spin Hall effect, and so that the spin current may flow into the magnetic free layer,
wherein the conductive layer includes the spin current-electric current conversion structure according to claim 1.

8. A method for making a thermoelectric conversion element, comprising:
stacking, on a substrate, a magnetic material layer containing a magnetic material exhibiting spin Seebeck effect;
stacking, on the magnetic material layer, an electromotive material connected to the magnetic material layer so that a spin current can flow into and out, and configured to generate electromotive force due to inverse spin Hall effect; and
forming two electrode sections apart from each other, each of which is electrically connected to the electromotive material,
wherein the stacking of the electromotive material includes forming the electromotive material in such a way as to include a spin current-electric current conversion structure, and
the spin current-electric current conversion structure includes
a 4d-transition metal oxide structure consisting primarily of an oxide containing a 4d-transition-metal element,
a spin current input-output structure configured to allow a spin current to flow into and out in a direction perpendicular to a plane of the 4d-transition metal oxide structure, and
an electric current input-output structure configured to allow an electric current to flow into and out, the electric current conducting in an in-plane direction of the 4d-transition metal oxide structure.

9. The method for making the thermoelectric conversion element according to claim 8, further comprising
performing thermal treatment, after forming the electromotive material including the spin current-electric current conversion structure, so that a valence of the 4d-transition metal in the oxide containing the 4d-transition-metal element may have a value by which to maximize a spin Hall angle of the oxide containing the 4d-transition-metal element.

10. The method for making the thermoelectric conversion element according to claim 8,
wherein the forming the electromotive material including the spin current-electric current conversion structure is performed by using a coating-based formation method.

11. The spin current-electric current conversion structure according to claim 2,
wherein the oxide containing the 4d-transition-metal element includes at least one of ruthenium oxide, rhodium oxide, and niobium oxide.

12. The spin current-electric current conversion structure according to claim 2,
wherein a thickness of the oxide containing the 4d-transition-metal element in a direction perpendicular to a plane of the oxide is not less than two nanometers and not more than thirty nanometers.

13. The spin current-electric current conversion structure according to claim 3,
wherein a thickness of the oxide containing the 4d-transition-metal element in a direction perpendicular to a plane of the oxide is not less than two nanometers and not more than thirty nanometers.

14. The thermoelectric conversion element according to claim 5,
wherein a valence of the 4d-transition metal in the oxide containing the 4d-transition-metal element is determined so that a spin Hall angle of the oxide containing the 4d-transition-metal element may be maximized.

15. The thermoelectric conversion element according to claim 5,
wherein the oxide containing the 4d-transition-metal element includes at least one of ruthenium oxide, rhodium oxide, and niobium oxide.

16. The thermoelectric conversion element according to claim 14,
wherein the oxide containing the 4d-transition-metal element includes at least one of ruthenium oxide, rhodium oxide, and niobium oxide.

17. The thermoelectric conversion element according to claim 5,
wherein a thickness of the oxide containing the 4d-transition-metal element in a direction perpendicular to a plane of the oxide is not less than two nanometers and not more than thirty nanometers.

18. The thermoelectric conversion element according to claim 14,
wherein a thickness of the oxide containing the 4d-transition-metal element in a direction perpendicular to a plane of the oxide is not less than two nanometers and not more than thirty nanometers.

19. The thermoelectric conversion element according to claim 15,
wherein a thickness of the oxide containing the 4d-transition-metal element in a direction perpendicular to a plane of the oxide is not less than two nanometers and not more than thirty nanometers.

20. The method for making the thermoelectric conversion element according to claim 9,
wherein the forming the electromotive material including the spin current-electric current conversion structure is performed by using a coating-based formation method.
